(19) United States
(12) Patent Application Publication
(10) Pub. No.: US 2008/0092942 A1
(43) Pub. Date: Apr. 24, 2008

(54) Front contact design for high-intensity solar cells and optical power converters

(75) Inventors: Geoffrey S. Kinsey, Pasadena, CA (US); Richard R. King, Thousand Oaks, CA (US)

Correspondence Address: CANADY & LORTZ LLP - BOEING, 2540 HUNTINGTON DRIVE, SUITE 205, SAN MARINO, CA, 91108, US

(73) Assignee: The Boeing Company, Chicago, IL (US)

(21) Appl. No.: 11/549,384

(22) Filed: Oct. 13, 2006

(51) Int. Cl. H01L 31/00

(52) U.S. Cl. 136/252

(57) ABSTRACT

Devices and methods are disclosed applicable to optical power converters such as solar cells comprising one or more photovoltaic layers for generating an electric potential between a top and bottom surface of the layers. A frontside metal contact is patterned on the top surface using a lithographic process such that open areas between metal features are contiguous. The pattern may include an opening between the contiguous open areas to an edge of the top surface of the layers. A pattern in this form facilitates easy removal of metal in these areas during device fabrication because liftoff of the unused metallization comprises removing metal as a contiguous piece, rather than multiple isolated regions. The opening to the edge further aids processing providing an entry path for solvent to dissolve the lithographic layer underlying the unused metallization.

### BACKGROUND OF THE INVENTION

1 Field of the Invention

This invention relates to optical power converters such as solar cells. Particularly, this invention relates to the efficient manufacturability and testability of solar cells, such as high-intensity solar cells, produced in large quantities.

2. Description of the Related Art

Recently, there has been increased interest in high-intensity optical power converters such as solar cells for both terrestrial power generation (e.g., concentrator solar cells operated under focused sunlight) and power beaming (e.g., laser power converters). High-intensity optical power converters should be designed to minimize resistive power losses. These are photovoltaic devices that are modified to operate under much higher light intensities than that normally provided, by direct sunlight for example. The highest-efficiency solar cells, for example, require a front contact metallization to extract current that is generated in the cell.

FIG. 1 illustrates a front contact metallization gridline pattern 102 for a conventional low intensity solar cell 100. This metal is typically deposited and patterned on the solar cell surface in a grid pattern 102 through known photolithographic processes. Openings 104 between the metal gridlines 106 allow light to reach the underlying active semiconductor (photovoltaic) material to generate the electrical current. Additional metallization along one edge of the solar cell connected to each of the gridlines 106 comprises the busbar 108 which serves as the collecting point for the generated current of the cell 100. However, high intensity light applications present some special design requirements.

When operated under high-intensity concentrated sunlight, large current densities are generated, e.g. typically on the order of 10 A/cm². In laser power converters, even higher densities may be obtained. In order to extract these higher electrical currents without significant resistive power loss, more of the front surface area (e.g. more than 10%) must be metallized than with a conventional lower light intensity application. However, this can lead to difficulties in device processing and testing, particularly when manufacturing large quantities of cells.

FIGS. 2A and 2B illustrate conventional front contact metallization gridline patterns for high intensity applications. FIG. 2A illustrates a high intensity rectangular cell 200 having a horizontal gridline pattern 202. FIG. 2B illustrates a high intensity circular cell 220 having a horizontal and vertical gridline pattern 222 connected to a conductive busbar perimeter 228. In both cases, the patterns 202, 222 require a greater density of gridlines 204, 224 due to the high intensity application. As a consequence of the high density of gridlines 204, 224, under a conventional design approach, a large number of enclosed areas 206, 226 are created between the gridlines 204, 224 isolated from one another.

During fabrication, metal must be removed from each of these enclosed areas 206, 226. Because the conventional metal gridline patterns 202, 222 for high intensity applications are more tightly spaced to minimize resistive power loss, it is more difficult to selectively remove the metal in the areas 206, 226 between metal gridlines 204, 224. Normal process variations can result in incomplete removal of metal in these enclosed areas. This difficulty can significantly increase processing time and decrease the device yield. Depending on the severity of the problem, this may result in decreased cell performance, expensive re-work, or complete loss of process lots.

In addition, in the case of the rectangular cell 200, multiple conductive busbars 208, 210 are needed to handle the additional current, minimizing resistive power losses. Each conductive busbar must be separately probed to fully test the cell 200.

In view of the foregoing, there is a need in the art for devices and methods to improve the manufacturability of optical power converters, such as solar cells. There is further a need for such devices and methods to accommodate a higher number of gridlines to handle the higher current densities associated with high intensity applications. In addition, there is a need for devices and methods which enable efficient testing of such solar cells, particularly in a high production processing. As detailed hereafter, these and other needs are met by the present invention.

### SUMMARY OF THE INVENTION

Embodiments of the invention are directed to devices and methods for optical power converters such as solar cells comprising one or more photovoltaic layers for generating an electric potential between a top and bottom surface of the layers. A frontside metal contact is patterned on the top surface using a lithographic process such that open areas between metal features are contiguous. In addition, the pattern may include an opening between the contiguous open areas to an edge of the top surface of the layers. A pattern in this form facilitates easy removal of metal in these areas during device fabrication because liftoff of the unused metallization comprises removing metal as a contiguous piece, rather than multiple isolated regions. The opening to the edge further aids processing providing an entry path for solvent to dissolve the lithographic layer underlying the unused metallization.

A typical embodiment of the invention comprises a device including one or more photovoltaic layers for generating an electric potential between a top surface and a bottom surface of the one or more photovoltaic layers from light photons and a pattern of conductive gridlines affixed to the top surface. The pattern forms a contiguous open area between the conductive gridlines and the conductive gridlines are for collecting electric current driven by the electric potential generated by the one or more photovoltaic layers from the light photons passing into the one or more photovoltaic layers through the contiguous open area between the conductive gridlines. In addition, the pattern may include at least one opening into the contiguous open area between the conductive gridlines at an edge of the top surface. The contiguous open area and the opening at the edge of the top surface facilitate easy removal of the excess material during the lithographic process used to produce the conductive gridlines.

In further embodiments of the invention, the pattern may comprise a continuous conductive busbar along three or more adjacent edges of the top surface connected to the pattern of conductive gridlines. The multiple busbars allow simple single point testing of the device. In one embodiment, the pattern may comprise a radial symmetric pattern.

In one exemplary embodiment, the pattern may comprise a set of parallel conductive gridlines extending from a conductive busbar at each opposing side of the top surface such that each set of parallel conductive gridlines do not contact each other. In this case, the pattern may further include ajoining conductive busbar coupling each opposing conductive busbar along an adjacent edge to each opposing conductive busbar. The contiguous open area between the conductive gridlines may be in a “fishbone” shape

Adding to the principle of sets of parallel conductive gridlines that do not contact each other, these gridlines may comprise horizontal conductive gridlines extending from vertical opposing conductive busbars at each vertical opposing side of the top surface. The pattern then further includes vertical conductive gridlines extending from horizontal opposing conductive busbars at each horizontal opposing side of the top surface such that none of the horizontal conductive gridlines and the vertical conductive gridlines contact each other. These horizontal and vertical conductive gridlines may extend to imaginary diagonal lines drawn through a center point of the pattern. In addition, the vertical opposing busbars and the horizontal opposing busbars may form a circular area occupied by the horizontal conductive gridlines and the vertical conductive gridlines. In this embodiment there may be at least one opening into the circular area along at least one of the vertical opposing busbars and the horizontal opposing busbars to an edge of the top surface.

Similarly, a typical method embodiment of the invention may include the steps of depositing one or more photovoltaic layers for generating an electric potential between a top surface and a bottom surface of the one or more photovoltaic layers from light photons, depositing and patterning a lithographic layer on the top surface of the one or more photovoltaic layers, the patterned lithographic layer for forming a pattern for conductive gridlines to contact the top surface, the pattern having a contiguous open area between the conductive gridlines, depositing a conductive layer over the patterned lithographic layer such that a portion of the conductive layer affixes to the top surface in the pattern for the conductive gridlines through the patterned lithographic layer, and removing the patterned lithographic layer including a remaining portion of the conductive layer to leave the pattern of conductive gridlines affixed to the top surface of the one or more photovoltaic layers. The method embodiment of the invention may be further modified consistent with the device embodiment described herein.

### BRIEF DESCRIPTION OF THE DRAWINGS

Referring now to the drawings in which like reference numbers represent corresponding parts throughout:

FIG. 1 illustrates a front contact metallization gridline pattern for a conventional low intensity solar cell;

FIGS. 2A and 2B illustrate conventional front contact metallization gridline patterns for high intensity applications;

FIGS. 3A to 3E illustrate a manufacturing sequence for an exemplary high intensity solar cell embodiment of the invention;

FIG. 4A illustrates an exemplary gridline pattern for a rectangular high intensity solar cell embodiment of the invention;

FIG. 4B illustrates an exemplary gridline pattern for a circular high intensity solar cell embodiment of the invention;

FIG. 4C illustrates an exemplary gridline pattern for a circular high intensity solar cell embodiment of the invention having radial symmetry; and

FIG. 5 is a flowchart for an exemplary method of manufacturing a high intensity solar cell embodiment of the invention.

### DETAILED DESCRIPTION OF THE PREFERRED EMBODIMENT

1. Overview

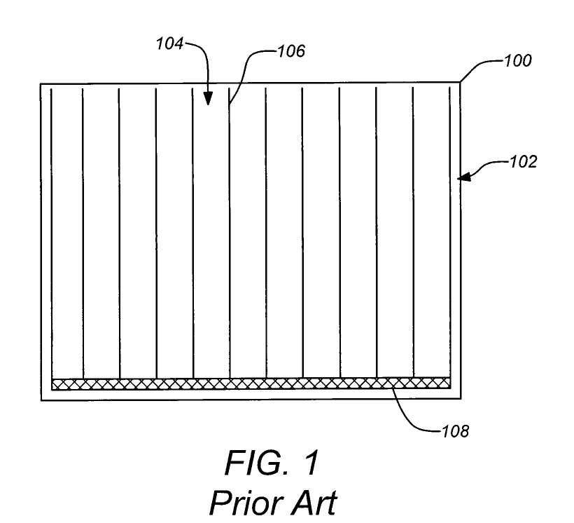

As previously mentioned, conventional gridline patterns for optical power converters under low-intensity operation may employ an open layout that avoids the problems described above. See FIG. 1, for example. However, the resistive power losses associated with this layout are prohibitive under the high-intensity operation used in applications such as concentrator solar cells and laser power converters. Such applications require metal gridline patterns that are more tightly spaced to minimize resistive power loss. This can make it difficult to selectively remove the metal in the openings between metal patterns. This can significantly increase process time and decrease the device yield. Embodiments of the invention overcome the difficulties inherent in processing devices with metal features that are tightly spaced in this manner.

Thus, removal of the metallization between the features proceeds faster and more consistently. For terrestrial power generation applications, low-cost production is essential. Without this approach, device processing is slower and residual metal is likely to remain on portions of the device, decreasing performance. Accordingly, embodiments of the invention can substantially increase device throughput and yield.

2. High Intensity Solar Cell Manufacturing Sequence

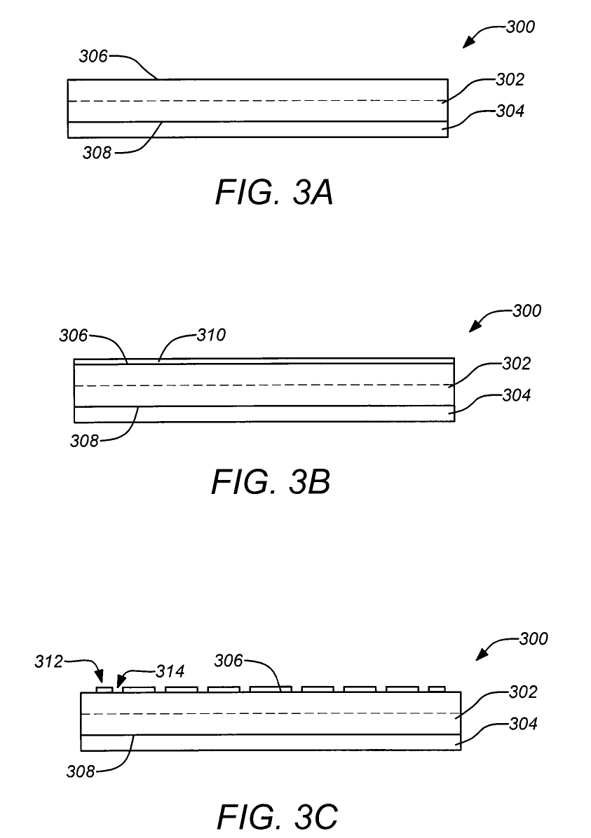

Generally, embodiments of the invention may be applied to any optical power converter which requires a pattern of conductive gridlines applied through a lithographic process. Embodiments of the invention define an architecture for the pattern of conductive gridlines that facilitates an efficient and accurate liftoff operation of the lithographic process. A typical manufacturing process of an optical power device embodiment of the invention is described hereafter as shown in FIGS. 3A to 3E illustrating a manufacturing sequence for an exemplary high intensity solar cell embodiment of the invention.

FIG. 3A illustrates a first stage of the manufacturing process of a solar cell 300 where one or more photovoltaic layers 302 are deposited. The photovoltaic layers 302 are typically deposited onto a conductive base substrate 304 such as germanium, silicon, gallium arsenide, indium phosphide, or gallium antimonide. The photovoltaic layers 302 generate an electric potential between a top surface 306 and a bottom surface 308 from light photons entering the top surface 306.

Embodiments of the invention are applicable to any type and combination of photovoltaic layers 302. For example, the one or more photovoltaic layers may comprise doped Si layers, GaAs layers, or alloys of Ga, As, Al, In, P, and/or Sb, or any other known materials capable of developing an electric potential under photon bombardment. Those skilled in the art will understand the various processes and materials that may be applied to develop photovoltaic layers as part of a functional device.

FIG. 3B illustrates the next stage of the manufacturing process where a lithographic layer 310 is applied to the top surface 306 of the photovoltaic layers 302. The lithographic layer 310 is developed with the desired pattern of gridlines for the final device. Patterning is usually performed with photoresist developer, a solvent-based process. Typically, the lithographic layer 310 is photoreactive such that, under exposure to a proper wavelength of light, areas of the lithographic layer 310 become more soluble in a a chemical developer solution applied later. The lithographic layer 310 is exposed to the light passed through a positive image of the desired pattern to prepare the layer 310 for the next patterning step. The optimal pattern which is an important consideration, will be described in the following section. (Note that a negative process known in the art may be equivalently employed within the scope of the invention, but it is less common.)

FIG. 3C illustrates the patterning process of the lithographic layer 310. A chemical solution is applied to the lithographic layer 310 and removes the layer 310 in all areas that were exposed to the developing light leaving the material of the patterned lithographic layer 312 only in areas that will later allow photons to enter the photovoltaic layers 302. Note that an important consideration in the development of the pattern is that the patterned lithographic layer 312 comprises contiguous regions as will be described hereafter. FIG. 3C shows the patterned lithographic layer 312 as having separate islands of material only for the purpose of illustrating the manufacturing process. This creates the pattern for the gridlines as exposed areas 314 of the top surface 306 of the photovoltaic layers 302.

FIG. 3D illustrates application of the conductive layer 316 over the patterned lithographic layer 312. The conductive layer fills into the exposed areas 314 and adheres to the top surface 306 of the photovoltaic layers 302. The conductive layer 316 is typically a metallic layer that will ultimately comprise the gridlines on the top surface 306 of the photovoltaic layers 302 of the finished device. For example, the conductive layer may be composed of layers of various metals such as gold, silver, titanium, platinum, and/or aluminum.

FIG. 3E illustrates the final liftoff step of the manufacturing process. In this step, a solvent is used to dissolve the patterned lithographic layer 312. All portions of the conductive layer 316 that were only supported by the patterned lithographic layer and are not affixed to the top surface 306 of the photovoltaic layers 302 are then lifted off of the device and torn away from the affixed portions of the conductive layer 316. This leaves a pattern of conductive gridlines 318 affixed to the top surface 306. Similarly, any required busbars 320 are formed along edges of the top surface 306. The conductive gridlines and busbars 320 are used to collect electric current driven by the electric potential generated by the one or more photovoltaic layers 302 from the light photons 322 passing into the one or more photovoltaic layers 302 through the contiguous open area between the conductive gridlines 318.

The open areas between metal features are connected in a contiguous pattern. This facilitates removal of metal in these selected areas. So-called “wet” processes (such as liftoff of photoresist or wet etching) are typically used to selectively remove metal. Thus, embodiments of the invention allow a solvent or etchant species to more readily penetrate between the metal features. Because the pattern of conductive gridlines 318 is formed having a contiguous open area between the conductive gridlines 318, the removed portions of conductive material may be efficiently lifted off as a single contiguous piece. This reduces process time and reduces the likelihood of incomplete metal removal. Further, in liftoff of photoresist (the typical process), the liftoff is enhanced because the metal to be removed is interconnected; liftoff of one section initiates liftoff of adjacent sections. Some exemplary patterns and an exemplary method of manufacturing will be detailed in the next section.

Various materials and processes for the lithographic development of metal patterns are known in the art. Those skilled in the art will appreciate that embodiments of the invention are applicable to any known manufacturing process of cells where a liftoff of portions of a conductive layer (e.g. metallization) is necessary to produce a conductive gridline pattern, particularly when dense gridlines patterns are required (such as in high intensity applications). Note also that, although the invention is described in the specification in relation to a solar cell, embodiments of the invention are not limited to this application but applicable to any optical power converting application employing conductive gridlines.

3. High Intensity Solar Cell and Method of Manufacturing

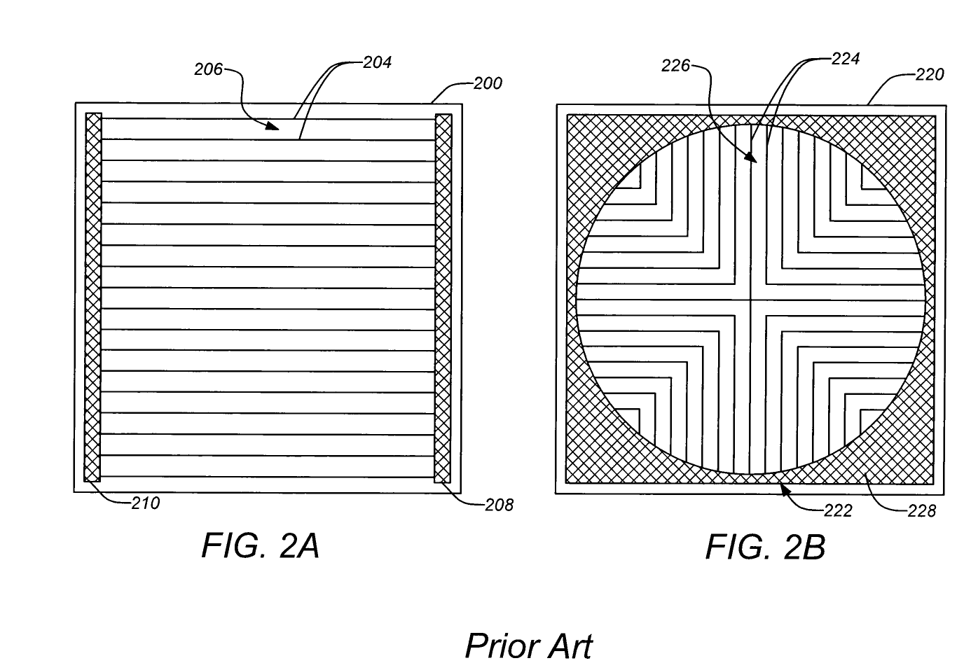

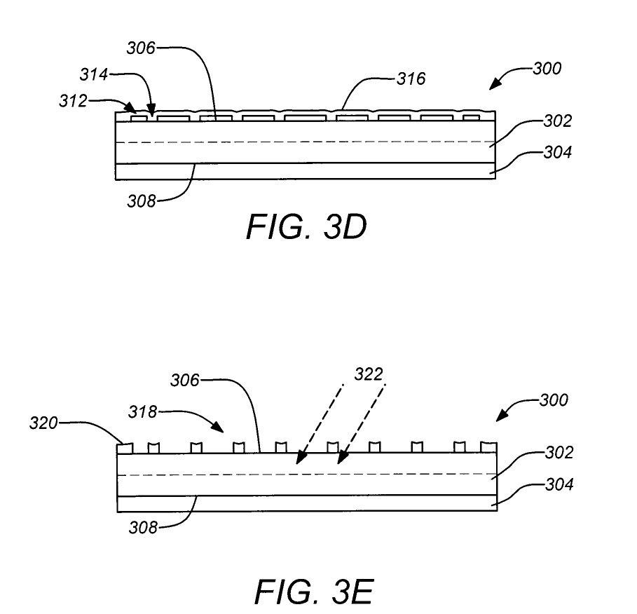

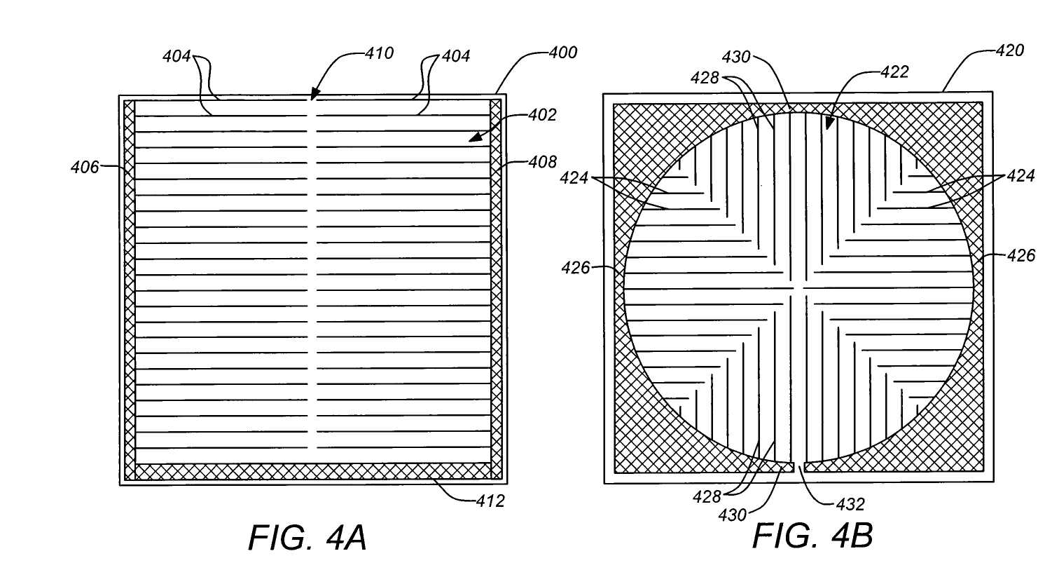

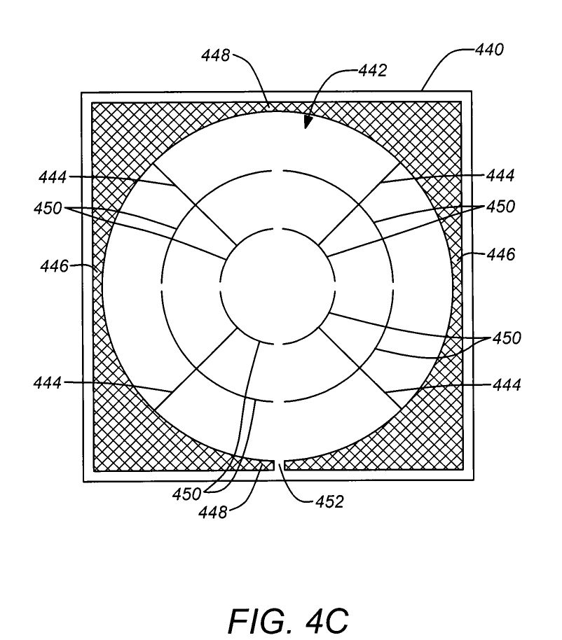

As illustrated in FIGS. 4A and 4B below, embodiments of the invention involve modification of conventional high-intensity contact layouts (e.g. as shown in FIGS. 2A and 2B) to obtain an open-ended gridline pattern. The patterns comprise gridlines which end somewhere in the interior of the top surface without contacting each other. By this principle, no closed areas are created between the gridlines. The interconnected spaces between metal features facilitate removal of the metal during processing. In addition, the busbars of a device may be connected by a third additional busbar to allow for single-point testing of both sides of the cell. This affords the high-intensity layout advantages improved over even those of the conventional low-intensity design such as are used in solar cells for space application (e.g. as shown in FIG. 1).

FIG. 4A illustrates an exemplary gridline pattern for a rectangular high intensity solar cell 400 embodiment of the invention. In this example, the gridline pattern 402 comprises two sets of parallel conductive gridlines 404, each extending from a conductive busbar 406, 408 at opposing sides of the top surface of the photovoltaic layers such that each set of parallel conductive gridlines do not contact each other. In the example shown, the contiguous open area between the conductive gridlines comprises a fishbone shape. This pattern 402 facilitates easy removal of the unused metallization because the conductive material in the contiguous area may be lifted off as a single element as previously described.

Another feature of the gridline pattern 402 is that there is an opening 410 into the contiguous open area between the conductive gridlines at an edge of the top surface. In this case, the opening 410 is along the upper edge of the pattern 402 as shown. This opening 402 is an additional feature that facilitates removal of the lithographic layer with portions of the conductive layer (metallization) during manufacturing. The solvent used to dissolve the lithographic layer is able to directly access the layer under the conductive layer through this side opening 410.

Yet another feature of the example pattern 402 is the addition of the busbar 412 along the third edge of the top surface which couples the two opposing busbars 406, 408 together along an adjacent edge to each opposing conductive busbar 406, 408. This joining busbar 412 allows testing of the finished device to be conducted through a single contact point (e.g. on the joining busbar 412) because the busbars 406, 408 are now shorted together. Separate testing of each busbar 406, 408 would otherwise be required. It should be noted that the opposing busbars 406, 408 may be sized smaller than the joining busbar 412 to increase the usable area of the cell (penetrated by photons), because the opposing busbars 406, 408 may carry less current than the joining busbar 412. Thus, the pattern 402 comprises a continuous conductive busbar along three adjacent edges of the top surface and connected to the pattern of conductive gridlines.

FIG. 4B illustrate an exemplary gridline pattern 422 for a circular high intensity solar cell 420 embodiment of the invention. This pattern 422 may be viewed as an extension of the pattern 402 of FIG. 4A. In addition to occupying a circular area (instead of a rectangular area), opposing sets of vertical parallel conductive gridlines are added to the opposing sets of horizontal parallel conductive gridlines. The horizontal conductive gridlines 424 extend from vertical opposing conductive busbars 426 at each vertical opposing side of the top surface. The pattern 422 further comprises vertical conductive gridlines 428 extending from horizontal opposing conductive busbars 430 at each horizontal opposing side of the top surface. In this case, none of the horizontal conductive gridlines 424 and the vertical conductive gridlines 428 contact each other to form the contiguous open area between the gridlines 424, 428. In the example of FIG. 4B, the horizontal and vertical conductive gridlines 424, 428 extend to imaginary diagonal lines drawn through a center point of the pattern 422.

Similar to the gridline pattern 422 of FIG. 4A, the gridline pattern of FIG. 4B also includes an opening 432 into the contiguous open area between the conductive gridlines 424, 428. In this case the opening is disposed along the lower horizontal busbar 430 at an edge of the top surface. This opening 430 facilitates removal of the lithographic layer with portions of the conductive layer (metallization) during manufacturing as solvent used to dissolve the lithographic layer is able to directly access the layer under the conductive layer through this side opening 432.

Another feature of the cell 420 of FIG. 4B is that the vertical opposing busbars 426 and the horizontal opposing busbars 430 form a circular area occupied by the horizontal conductive gridlines 424 and the vertical conductive gridlines 428. Note that although the busbars 426, 430 have circular edges toward the interior of the cell they are still considered “vertical” and “horizontal” as defined by their position along the edge of the top surface.

Finally, it should also be noted that the foregoing patterns 400, 420 of FIGS. 4A and 4B are only examples. Those skilled in the art will appreciate that other patterns having contiguous open areas between conductive gridlines and (optional) openings into those areas from top surface edges may be developed within the scope of the invention. The cells may be made in other than rectangular shapes (e.g., circular or other polygon shapes) and any number of alternate gridlines patterns may be created where gridlines end without contacting each other to leave a contiguous open area in the cell interior. For example, many circular wafers are currently being produced.

FIG. 4C illustrates another exemplary gridline pattern for a circular high intensity solar cell 440 embodiment of the invention having radial symmetry. In this case, the radial symmetric pattern 442 comprises radial conductive gridlines 444 extending from the vertical and horizontal busbars 446, 448 forming a circular area. The radial conductive gridlines 444 are connected to further concentric arc conductive gridlines 450. As shown, this radial symmetric pattern 442 also maintains a contiguous open area to facilitate removal of metallization as previously discussed. Similar to the previous embodiment, this pattern 442 also includes an opening 452 into the contiguous open area between the conductive gridlines. Additional radial and/or concentric arc conductive gridlines 444, 450 may be added to the pattern as desired. An exemplary method of manufacturing an embodiment of the invention is described hereafter to apply a pattern in accordance with the principles described.

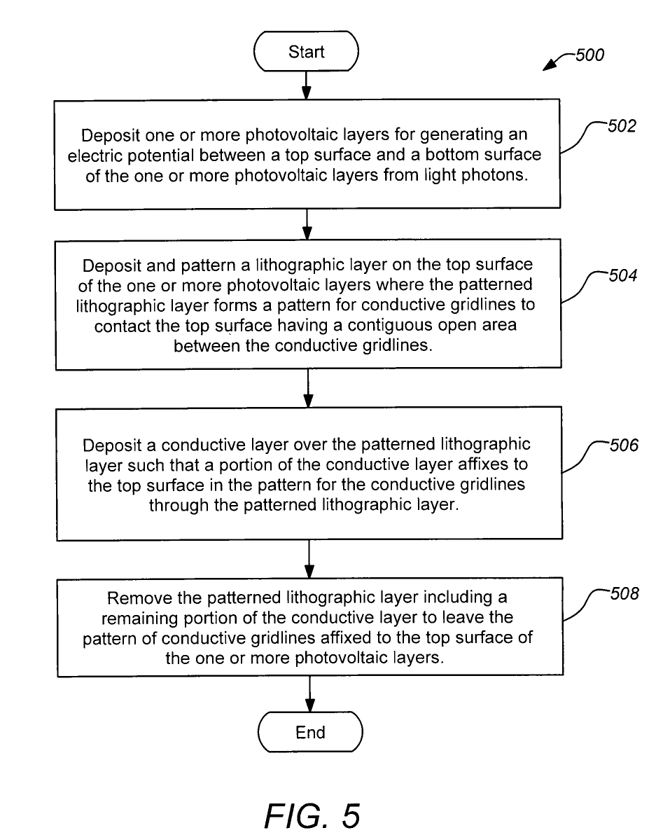

FIG. 5 is a flowchart for an exemplary method 500 of manufacturing a high intensity solar cell embodiment of the invention. The method 500 begins with the operation 502 of depositing one or more photovoltaic layers for generating an electric potential between a top surface and a bottom surface of the one or more photovoltaic layers from light photons. For example, the one or more photovoltaic layers (e.g. properly doped GaAs, Si, etc.) may be deposited onto a conductive substrate. Next in operation 504, a lithographic layer is deposited and patterned on the top surface of the one or more photovoltaic layers. The patterned lithographic layer forms a pattern for conductive gridlines to contact the top surface having a contiguous open area between the conductive gridlines. In operation 506, a conductive layer is deposited over the patterned lithographic layer such that a portion of the conductive layer affixes to the top surface in the pattern for the conductive gridlines through the patterned lithographic layer. Finally, in operation 508, the patterned lithographic layer is removed including the remaining portions of the conductive layer to leave the pattern of conductive gridlines affixed to the top surface of the one or more photovoltaic layers. The method 500 is further illustrated by the manufacturing sequence shown in FIGS. 3A-3E. In addition, the method 500 may be further modified consistent with the apparatus embodiments described herein.

This concludes the description including the preferred embodiments of the present invention. The foregoing description including the preferred embodiment of the invention has been presented for the purposes of illustration and description. It is not intended to be exhaustive or to limit the invention to the precise forms disclosed. Many modifications and variations are possible within the scope of the foregoing teachings. Additional variations of the present invention may be devised without departing from the inventive concept as set forth in the following claims.

What is claimed is:

1. An apparatus comprising:
one or more photovoltaic layers for generating an electric potential between a top surface and a bottom surface of the one or more photovoltaic layers from light photons; and
a pattern of conductive gridlines affixed to the top surface, the pattern forming a contiguous open area between the conductive gridlines, the conductive gridlines for collecting electric current driven by the electric potential generated by the one or more photovoltaic layers from the light photons passing into the one or more photovoltaic layers through the contiguous open area between the conductive gridlines.

2. The apparatus of claim 1, wherein the pattern comprises at least one opening into the contiguous open area between the conductive gridlines at an edge of the top surface.

3. The apparatus of claim 1, wherein the pattern comprises a radial symmetric pattern.

4. The apparatus of claim 1, wherein the pattern comprises a continuous conductive busbar along three or more adjacent edges of the top surface and connected to the pattern of conductive gridlines.

5. The apparatus of claim 1, wherein the pattern comprises a set of parallel conductive gridlines extending from a conductive busbar at each opposing side of the top surface such that each set of parallel conductive gridlines do not contact each other.

6. The apparatus of claim 5, wherein the pattern further comprises a joining conductive busbar coupling each opposing conductive busbar along an adjacent edge to each opposing conductive busbar.

7. The apparatus of claim 5, wherein the contiguous open area between the conductive gridlines comprises a fishbone shape.

8. The apparatus of claim 5, wherein the set of parallel conductive gridlines extending from the conductive busbar at each opposing side of the top surface comprise horizontal conductive gridlines extending from vertical opposing conductive busbars at each vertical opposing side of the top surface and the pattern further comprises vertical conductive gridlines extending from horizontal opposing conductive busbars at each horizontal opposing side of the top surface such that none of the horizontal conductive gridlines and the vertical conductive gridlines contact each other.

9. The apparatus of claim 8, wherein the horizontal conductive gridlines and the vertical conductive gridlines extend to imaginary diagonal lines drawn through a center point of the pattern.

10. The apparatus of claim 8, wherein the vertical opposing busbars and the horizontal opposing busbars form a circular area occupied by the horizontal conductive gridlines and the vertical conductive gridlines.

11. The apparatus of claim 10, wherein there is at least one opening into the circular area along at least one of the vertical opposing busbars and the horizontal opposing busbars to an edge of the top surface.

12. A method comprising the steps of:
depositing one or more photovoltaic layers for generating an electric potential between a top surface and a bottom surface of the one or more photovoltaic layers from light photons;
depositing and patterning a lithographic layer on the top surface of the one or more photovoltaic layers, the patterned lithographic layer for forming a pattern for conductive gridlines to contact the top surface, the pattern having a contiguous open area between the conductive gridlines;
depositing a conductive layer over the patterned lithographic layer such that a portion of the conductive layer affixes to the top surface in the pattern for the conductive gridlines through the patterned lithographic layer; and
removing the patterned lithographic layer including a remaining portion of the conductive layer to leave the pattern of conductive gridlines affixed to the top surface of the one or more photovoltaic layers.

13. The method of claim 12, wherein the pattern comprises at least one opening into the contiguous open area between the conductive gridlines at an edge of the top surface.

14. The method of claim 12, wherein the pattern comprises a radial symmetric pattern.

15. The method of claim 12, wherein the pattern comprises a continuous conductive busbar along three or more adjacent edges of the top surface and connected to the pattern of conductive gridlines.

16. The method of claim 12, wherein the pattern comprises a set of parallel conductive gridlines extending from a conductive busbar at each opposing side of the top surface such that each set of parallel conductive gridlines do not contact each other.

17. The method of claim 16, wherein the pattern further comprises a joining conductive busbar coupling each opposing conductive busbar along an adjacent edge to each opposing conductive busbar.

18. The method of claim 16, wherein the contiguous open area between the conductive gridlines comprises a fishbone shape.

19. The method of claim 16, wherein the set of parallel conductive gridlines extending from the conductive busbar at each opposing side of the top surface comprise horizontal conductive gridlines extending from vertical opposing conductive busbars at each vertical opposing side of the top surface and the pattern further comprises vertical conductive gridlines extending from horizontal opposing conductive busbars at each horizontal opposing side of the top surface such that none of the horizontal conductive gridlines and the vertical conductive gridlines contact each other.

20. The method of claim 19, wherein the vertical opposing busbars and the horizontal opposing busbars form a circular area occupied by the horizontal conductive gridlines and the vertical conductive gridlines.

21. The method of claim 20, wherein there is at least one opening into the circular area along at least one of the vertical opposing busbars and the horizontal opposing busbars to an edge of the top surface.

22. The method of claim 12, wherein the conductive gridlines are for collecting electric current driven by the electric potential generated by the one or more photovoltaic layers from the light photons passing into the one or more photovoltaic layers through the contiguous open area between the conductive gridlines.

23. An apparatus comprising:
a photovoltaic means for generating an electric potential between a top surface and a bottom surface of the one or more photovoltaic layers from light photons; and
a conductive means for collecting electric current driven by the electric potential generated by the one or more photovoltaic layers, the conductive means affixed to the top surface and patterned to form a contiguous open area for the light photons to pass into the one or more photovoltaic layers through the contiguous.
